(19) United States
(12) Patent Application Publication
(10) Pub. No.: US 2011/0005921 A1
(43) Pub. Date: Jan. 13, 2011

(54) METHOD FOR MAKING A THIN LAYER SOLID OXIDE FUEL CELL, A SO-CALLED SOFC

(76) Inventor: Pascal Brault, Saint Denis En Val (FR)

Correspondence Address: HARNESS, DICKEY & PIERCE, P.L.C., P.O. BOX 828, BLOOMFIELD HILLS, MI, 48303, US

(21) Appl. No.: 12/808,945

(22) PCT Filed: Dec. 18, 2008
(86) PCT No.: PCT/EP08/67863

§ 371 Date: Jun. 17, 2010

(30) Foreign Application Priority Data
Dec. 20, 2007 (FR) 0760124

(51) Int. Cl. C23C 14/35

(52) U.S. Cl. 204/192.15

(57) ABSTRACT

The present disclosure relates to a method for making a thin layer solid oxide fuel cell including at least an anode, an electrolyte and a cathode including at least the following steps of:
magnetron sputtering deposition of an electrolyte on a first electrode, and of
magnetron sputtering deposition of a second electrode on the electrolyte,

at least one catalyst is incorporated into the first electrode and/or the second electrode during the deposition thereof.

### CROSS-REFERENCE TO RELATED APPLICATIONS

This application is a National Phase Entry of International Application No. PCT/EP2008/067863, filed on Dec. 18, 2008, which claims priority to French Application 0760124, filed on Dec. 20, 2007, both of which are incorporated by reference herein.

### BACKGROUND AND SUMMARY

The present invention relates to the field of thin layer solid oxide fuel cells, so-called SOFCs (Solid Oxide Fuel Cells) and more particularly to the method for making them.

It is well-known that fuel cells are used in many applications, and are notably considered as a possible alternative to the use of fossil fuels. Indeed, these cells allow direct conversion of a source of chemical energy for example hydrogen or ethanol into electric energy.

A thin layer fuel cell of the SOFC type usually consists, with reference to FIG. 1 which is a schematic illustration of a fuel cell, of an ion-conducting electrolyte 1, in which are deposited on either side an anode 2 and a cathode 3. The operating principle of such a cell is the following: the anode 2 is the center of the reaction 2H₂+2O²⁻→2H₂O+4e⁻, the electrolyte 1 being responsible for transporting the O²⁻ ion and the cathode 3 is the center of the following reaction: O₂+4e⁻→2O²⁻ when the cell is supplied with hydrogen (H₂) and oxygen (O₂). The anode 2 and the cathode 3 have to be obtained in a porous material in order to ensure accessibility of the gases and to provide discharge of the water produced by the cell.

Moreover, the anode 2 and the cathode 3 have to be electrically conducting in order to ensure transport of the current. Further, the electrolyte 1 has to be obtained in a dense and ion-conducting material in order to provide the transport of the O²⁻ ion. Thus, these fuel cells usually consist of an anode 2 in Cermet Ni—ZrO₂-8% Y₂O₃, of an electrolyte 1 in ZrO₂-8% Y₂O₃(YSZ) and a cathode 3 in LaSrMnO_{3-δ} (LSM). The usual methods for making these SOFC fuel cells are the formation of successive layers forming the anode 2, the electrolyte 1 and the cathode 3 by strip casting, by screen-printing, by spin coating, by thermal plasma projection or by flame spraying for example.

However, the fuel cells obtained according to these methods have too high operating temperatures, comprised between 700 and 1,000° C., for applications in the fields of domestic power auxiliaries and transportation. One of the objects of the invention is therefore to find a remedy to these drawbacks by proposing a method for making fuel cells having a low operating temperature, i.e. below 400° C.

According to the invention, a method for making a thin layer solid oxide fuel cell is proposed including at least an anode, an electrolyte and a cathode remarkable in that it includes at least the following steps of magnetron sputtering of an electrolyte on a first electrode, and then of magnetron sputtering of a second electrode on the electrolyte, and in that at least one catalyst is incorporated into the first electrode and/or the second electrode during their deposition. The first electrode and/or the second electrode therefore advantageously includes at least one catalyst distributed in said electrode. Said catalyst is preferably comprised in an element or a combination of at least two elements from the group comprising the platinum group, platinoid alloys such as platinum-ruthenium, platinum-molybdenum, platinum-tin, non-platinoid metals such as iron, nickel or cobalt. Said platinum group includes platinum (Pt), palladium (Pd), ruthenium (Ru), rhodium (Rh), osmium (Os) and iridium (Ir).

The first electrode, the electrolyte and the second electrode are successively deposited in a chamber including at least 3 magnetron targets. The depositions are preferably carried out under an oxidizing atmosphere. According to a feature of the method according to the invention, the depositions are carried out with an ionized reactive magnetron plasma sputtering method. Said plasma is a plasma containing at least oxygen and preferably an argon-oxygen mixture. Moreover, the pressure in the chamber is variable. The first electrode is obtained by magnetron sputtering deposition on a supporting substrate.

Said supporting substrate consists in a substrate capable of being dissolved in a liquid, said liquid not dissolving the electrodes and the electrolyte of the fuel cell. Said first electrode forming the anode of the fuel cell is obtained by magnetron sputtering of a Ni-YSZ or Sr₁₋ₓYₓTiO₃ target under an oxidizing atmosphere. The bias of the target and/or the pressure of the plasmagen gas and/or the speed of rotation of the supporting substrate are continuously adjusted during sputtering in order to vary the porosity in the depth of the deposited layer forming the first electrode.

According to an alternative embodiment, the first electrode forming the anode or the cathode forms a supporting substrate obtained in an electron conducting or ion/electron conducting and porous reducing oxide, on which are deposited the electrolyte and the cathode or respectively the anode.

Moreover, the electrolyte of the fuel cell is obtained by magnetron sputtering of a yttriated zirconia target or CeO₂ doped with Sm₂O₃ or Gd₂O₃ under an oxidizing atmosphere. Sputtering is obtained by pulsed magnetron sputtering. The second electrode forming the cathode of the fuel cell is obtained by magnetron sputtering of a target of LaₓSr₁₋ₓMnO₃ (LSM) of LaNiO_{4+δ} or NdₓNiO_{4+δ} under an oxidizing atmosphere. The bias of said target and/or the pressure of the plasmagen gas and/or the speed of rotation of the supporting substrate is continuously adjusted during sputtering in order to vary porosity in the depth of the deposited layer forming the second electrode.

### BRIEF DESCRIPTION OF THE DRAWINGS

Other advantages and characteristics will become better apparent from the description which follows, of several alternative embodiments, given as non-limiting examples, of the method for making a fuel cell of the SOFC type according to the invention, from appended drawings wherein:

FIG. 1 is a schematic illustration of a fuel cell; and

FIG. 2 is a schematic illustration of a vacuum chamber of a magnetron sputtering deposition device for applying the method according to the invention.

### DETAILED DESCRIPTION

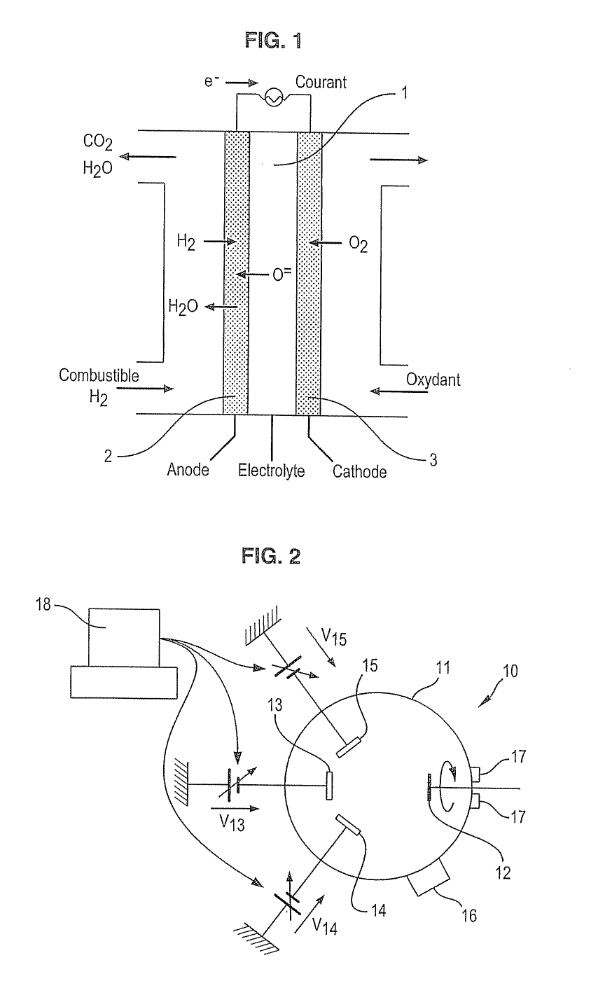

With reference to FIG. 1, the fuel cell consists of an ion-conducting electrolyte 1, on which an electrode, more specifically an anode 2 and a cathode 3 are deposited on either side. The electrolyte 1 is preferably made in yttriated zirconia (YSZ), and more specifically in 8% yttriated zirconia (YSZ) having a high density in order to optimize conduction of O₂ ions in the fuel cell. Said density should be close to 6.10 g/cm³. Said electrolyte 1 may also be obtained in CeO₂ doped with Sm₂O₃or Gd₂O₃ for example.

The anode 2 is preferably made in yttriated zirconia, Cermet Ni-YSZ, the porosity of which is advantageously variable in the depth of the layer forming the anode 2, the average porosity being of the order of 50%. Said anode 2 may advantageously include at least one catalyst distributed in said anode 2. Said catalyst consists in an element or a combination of at least two elements from the group comprising the platinum group, platinoid alloys such as platinum-molybdenum, platinum-tin, and non-platinoid metals such as iron (Fe), nickel (Ni) or cobalt (Co). The group of platinum notably includes platinum (Pt), palladium (Pd), ruthenium (Ru), rhodium (Rh), osmium (Os) and iridium (Ir).

Accessorily, the catalyst concentration increases from the outer face towards the inner face of the anode 2, i.e. from the free face of the anode 2 towards the electrolyte 1, in order to improve the efficiency of use of said catalyst. It will be observed that the anode 2 may also notably be obtained by deposition of Sr₁₋ₓYₓTiO₃.

The cathode 3 is made in LaₓSr₁₋ₓMnO₃ (LSM) and advantageously includes a catalyst as described earlier for the anode 2. Moreover, the average porosity of the cathode 3 is also of the order of 50%. Accessorily, and in the same way as for the anode 2, the catalyst concentration increases from the outer face towards the inner face of the cathode 3, i.e. from the free face of the cathode 3 towards the electrolyte 1, in order to improve the efficiency of use of said catalyst. Further, said porosity may advantageously be variable in the depth of the layer forming the cathode 3. It will be observed that the cathode 3 may also be obtained by deposition of LaNiO_{4+δ} or NdₓNiO_{4+δ}.

For making this fuel cell, with reference to FIG. 2, a possibly ionized reactive magnetron plasma sputtering device 10 is used. This magnetron sputtering device 10 consists of a vacuum chamber 11, with a generally cylindrical shape for example, in which a support-holder 12 and at least three magnetron targets 13, 14 and 15 extend. The support-holder 12 is capable of being driven into rotation around the normal to the main face of the latter so as to allow uniform deposition of different materials.

The magnetron targets 13, 14 and 15 are respectively biased with variable voltages V13, V14 and V15. The first target 13 is for example a target of yttriated zirconia (YSZ), and more specifically in 8% yttriated zirconia (YSZ), for making the electrolyte 1. The second target 14 is for example a target of yttriated zirconia, Cermet Ni-YSZ, for making the anode 2 and the third target 15 is a target of LaₓSr₁₋ₓMnO₃ (LSM) for making the cathode 3. Accessorily, the device includes a fourth target, not illustrated in FIG. 2, for sputtering a catalyst simultaneously with the sputtering of the material of the anode 2 and/or of the cathode 3.

The device moreover includes a radiofrequency emission source 16, such as a radiofrequency antenna, in order to generate additional plasma in the chamber 11, preferably a plasma containing oxygen, such as an argon-oxygen plasma for example, and to control the oxidization rate of the layers. The oxygen flow may for example be comprised between 0 and 50% and the argon flow may be comprised between 1 and 50% for example.

Moreover, the device includes one or more magnets 17, permanent magnets and/or electromagnets, positioned under the support-holder 12 and capable of trapping the low pressure plasma in proximity to the support-holder 12. Preferably this is a low pressure plasma of argon, or of any other gas having a mass close to the mass of the target. By low pressure plasma is meant a plasma for which the pressure is comprised between 0.1 and 100 mTorrs. Further, the device may advantageously include a computer 18 in which one or more time diagrams are recorded in memory and which is capable of controlling the variable voltages V13, V14 and V15 so as to obtain the desired profile.

The making method consists of placing a supporting substrate on the support-holder 12 of the possibly ionized reactive magnetron plasma sputtering device 10. Said supporting substrate may consist in a substrate capable of being dissolved in a liquid, said liquid not dissolving the electrodes 2, 3 and the electrolyte 1 of the fuel cell. The anode 2 is made by sputtering of the Ni-YSZ target 14 on the supporting substrate under an oxidizing atmosphere in order to be able to control the oxygen level, either with or without assistance from the radiofrequency emission source 16. The thereby obtained anode 2 is in Cermet Ni-YSZ (yttriated zirconia), the porosity of which may be variable in the depth of the layer by continuously adjusting the parameters for biasing the magnetron sputtering target 14 and/or the pressure of the plasmagen gas and/or the speed of rotation of the support-holder, said biasing parameters being adjusted by means of the variable voltage V14.

According to an alternative embodiment of the method according to the invention, the deposition of the layer forming the anode 2 is achieved by reactive magnetron sputtering of an Ni—Y—Zr alloy under a mixed argon-oxygen plasma, with or without the assistance of the radiofrequency emission source 16.

Moreover, it will be observed that with the variation of argon pressure and/or the variation of bias and/or the variation of the speed of rotation of the supporting substrate, the porosity of the anode 2 may be controlled, the average porosity being usually close to 50%. It will be noted that the person skilled in the art may easily adjust the porosity, by oxidation tests at this anode 2, depending on the targeted application for the fuel cell. For low temperature operation, i.e. at a temperature below 400° C., it is easy to incorporate a catalyst into the Ni-YSZ layer forming the anode 2 during deposition by co-sputtering or by using an additional target not illustrated in the figures.

Said catalyst consists in an element or in a combination of at least two elements from the group comprising the platinum group, platinoid alloys such as platinum-molybdenum, platinum-tin, and non-platinoid metals such as iron (Fe), nickel (Ni) or cobalt (Co). The platinum group notably includes platinum (Pt), palladium (Pd), ruthenium (Ru), rhodium (Rh), osmium (Os) and iridium (Ir). Accessorily, co-sputtering may be achieved in such a way that the platinum concentration decreases towards the inside of the anode 2 in order to reduce its amount and improve its efficiency of use.

After the deposition of the anode 2 on the supporting substrate 2, the target 13 of yttriated zirconia is sputtered under an oxygen atmosphere with or without the assistance of the radiofrequency emission source, preferably by pulsed magnetron sputtering, in order to deposit a layer forming the electrolyte 1 on the anode 2. It will be observed that the thereby deposited electrolyte 1 should have high density, of about 6.10 g/cm³, in order to optimize conduction of O²⁻ ions in the lattice of the electrolyte 1 of the fuel cell. Further, this pulsed magnetron sputtering technique is particularly suitable for sputtering insulating targets while retaining the performances of continuous sputtering depositions.

Finally, the cathode 3 is deposited on the electrolyte 1 from the target LaₓSr₁₋ₓMnO₃ (LSM) 15, said target 15 being sputtered under an oxidizing atmosphere in order to preserve oxygen stoichiometry. Said target 15 advantageously contains a catalyst for better operation at low temperature. In the same way as earlier, said catalyst consists in an element or a combination of at least two elements of the group comprising the platinum group, platinoid alloys such as platinum-molybdenum, platinum-tin, and non-platinoid metals such as iron (Fe), nickel (Ni) or cobalt (Co), the platinum group notably including platinum (Pt), palladium (Pd), ruthenium (Ru), rhodium (Rh), osmium (Os) and iridium (Ir).

Moreover, it will be noted that by varying argon pressure and/or by varying bias and/or by varying the speed of rotation of the supporting substrate, it is possible to control the porosity of the cathode 3, the average porosity being usually close to 50%. The anode 2, electrolyte 1 and cathode 3 assembly is detached from the supporting substrate by any suitable means well-known to the person skilled in the art.

According to an alternative embodiment of the method for making a fuel cell according to the invention, the electrolyte 1 and then the cathode 3 may be deposited on a supporting substrate consisting of a substrate forming the anode 2, said substrate forming the anode 2 being obtained in an electron conducting or ion/electron conducting reducing oxide, such as yttriated zirconia Cermet Ni-YSZ, or Sr₁₋ₓYₓTiO₃, for example, without however departing from the scope of the invention. According to another alternative embodiment of the method for making a fuel cell according to the invention, the electrolyte 1 and then the anode 2 may be deposited on a supporting substrate consisting of a substrate forming the cathode 3, said substrate forming the cathode 3 being obtained in an electron conducting or ion/electron conducting reducing oxide, such as in yttriated zirconia Cermet Ni-YSZ, or Sr₁₋ₓYₓTiO₃ for example, without however departing from the scope of the invention.

The electrolyte 1 may be obtained by magnetron sputtering deposition of CeO₂ doped with Sm₂O₃ or Gd₂O₃ for example, that the anode 2 may be obtained by magnetron sputtering deposition of Sr₁₋ₓYₓTiO₃ and that the cathode 3 may be obtained by magnetron sputtering deposition of LaNiO_{4+δ} or NdₓNiO_{4+δ}, the targets 13, 14 and 15 being adapted accordingly. Moreover, the electrolyte 1 may be obtained in any ion-conducting oxide and that the anode 2 and/or the cathode 3 may be obtained in any electron-conducting oxide and/or in any mixed electron/ion conducting oxide, without however departing from the scope of the invention. Finally, the examples which have just been given are only particular illustrations and by no means limiting as to the fields of application of the invention.

1. A method for making a thin layer solid oxide fuel cell including at least an anode, an electrolyte and a cathode, the method comprising:
magnetron sputtering deposition of an electrolyte on a first electrode;
magnetron sputtering deposition of a second electrode on the electrolyte; and
incorporating at least one catalyst into at least one of the electrodes during the deposition thereof.

2. The method of claim 1, wherein the catalyst comprises at least one element taken from the group comprising:
a platinum group;
platinoid alloys; and
non-platinoid metals.

3. The method of claim 2, wherein the platinum group includes platinum (Pt), palladium (Pd), ruthenium (Ru), rhodium (Rh), osmium (Os) and iridium (Ir).

4. The method of claim 1 wherein the first electrode, the electrolyte and the second electrode are successively deposited in a chamber including a least 3 magnetron targets.

5. The method of claim 1 wherein the depositions are carried out under an oxidizing atmosphere.

6. The method of claim 1 wherein the depositions are carried out with an ionized reactive magnetron plasma sputtering method.

7. The method of claim 6, wherein the plasma is a plasma containing at least oxygen.

8. The method of claim 7, wherein the plasma is an argon-oxygen mixture.

9. The method of claim 5 wherein the pressure in the chamber is variable.

10. The method of claim 1 wherein the first electrode is obtained by magnetron sputtering deposition on a supporting substrate.

11. The method of claim 10, wherein the supporting substrate includes a substrate capable of being dissolved in a liquid, the liquid not dissolving the electrodes and the electrolyte of the fuel cell.

12. The method of claim 4, wherein the first electrode forming the anode of the fuel cell is obtained by magnetron sputtering of a Ni-YSZ or Sr₁₋ₓYₓTiO₃ target under an oxidizing atmosphere.

13. The method of claim 12, wherein the bias of at least one of: (a) the target, (b) the pressure of the plasmagen gas, and (c) the speed of rotation of the supporting substrate continuously adjusted during sputtering in order to vary the porosity in the depth of the deposited layer.

14. The method of claim 1, wherein the first electrode forming the anode or the cathode forms a supporting substrate obtained in a porous electron-conducting or ion/electron-conducting reducing oxide, and on which the electrolyte and the cathode or respectively the anode are deposited.

15. The method of claim 1, wherein the electrolyte of the fuel cell is obtained by magnetron sputtering of a target of yttriated zirconia (YSZ) or of CeO₂ doped with Sm₂O₃ or Gd₂O₃ under an oxidizing atmosphere.

16. The method of claim 15, wherein sputtering is obtained by pulsed magnetron sputtering.

17. The method of claim 1, wherein the second electrode forming the cathode of the fuel cell is obtained by magnetron sputtering of a target of LaₓSr₁₋ₓMnO₃ (LSM) of LaNiO_{4+δ} or NdₓNiO_{4+δ} under an oxidizing atmosphere.

18. The method of claim 17, wherein the bias of at least one of: (a) the target, (b) the pressure of the plasmagen gas, and (c) the speed of rotation of the supporting substrate, is continuously adjusted during sputtering in order to vary the porosity in the depth of the deposited layer.
